(19) United States
(12) Patent Application Publication
(10) Pub. No.: US 2026/0366673 A1
(43) Pub. Date: Nov. 19, 2026

(54) HOLDER FOR AN ELECTRONIC DEVICE OR THE LIKE

(71) Applicant: GRIP TRIP PTY LTD, Coogee, New South Wales (AU)

(72) Inventors: Craig Alan STIRLING, Coogee, New South Wales (AU); Colin SCHMIDT, Redfern, New South Wales (AU)

(21) Appl. No.: 19/155,110

(22) PCT Filed: Feb. 12, 2024
(86) PCT No.: PCT/AU2024/050088

§ 371 Date: Aug. 8, 2025

(30) Foreign Application Priority Data
Feb. 10, 2023 (AU) 2023900330

(51) Int. Cl. F16M 11/38; F16M 11/04

(52) U.S. Cl. CPC F16M 11/38; F16M 11/041

(57) ABSTRACT

A holder for an electronic device or the like. The device holder including a first resiliently deformable member including a first end and a second end; a second resiliently deformable member including a first end and a second end, the second resiliently deformable member being connected to the first resiliently deformable member at the respective first ends; and a first engaging formation connected to the second end of the first deformable member; a second engaging formation connected to the second end of the second deformable member, wherein, in the closed position, the first deformable member and the second deformable member are coplanar, and wherein in the open position, the second end of the first deformable member and the second end of the second deformable member are disposed away from each other to hold an electronic device between the engaging formations of the first deformable member and the second deformable member.

### RELATED APPLICATIONS

This application claims the priority of Australian Provisional Patent Application No. 2023900330 filed in the name of Platinum Endeavours Pty Ltd (assigned to Grip Trip Pty Ltd), which was filed on 10 Feb. 2023, entitled “Electronic Device Holder” and the specification thereof is incorporated herein by reference in its entirety and for all purposes.

### FIELD OF INVENTION

The present invention relates to a holder for an electronic device, and in particular to such a holder for use during travel.

While the invention has been developed primarily for use during travel and will be described in some aspects hereinafter with reference to this application, it will be appreciated that the invention is not limited to this particular field of use.

In one particular aspect the present invention is suitable for use as a holder for a smartphone or tablet device.

It will be convenient to hereinafter describe the invention in relation to its function to hold, protect and/or store a smartphone or tablet device while travelling, however it should be appreciated that the present invention is not limited to that use(s), only.

### BACKGROUND ART

Throughout this specification the use of the word “inventor” in singular form may be taken as reference to one (singular) inventor or more than one (plural) inventor of the present invention.

It is to be appreciated that any discussion of documents, devices, acts or knowledge in this specification is included to explain the context of the present invention. Further, the discussion throughout this specification comes about due to the realisation of the inventor and/or the identification of certain related art problems by the inventor. Moreover, any discussion of material such as documents, devices, acts or knowledge in this specification is included to explain the context of the invention in terms of the inventor's knowledge and experience and, accordingly, any such discussion should not be taken as an admission that any of the material forms part of the prior art base or the common general knowledge in the relevant art in Australia, or elsewhere, on or before the priority date of the disclosure and claims herein.

Presently, people who wish to watch content on their mobile device need to hold their mobile device in their hands, unless they carry a mobile device stand or have a case around the mobile device that includes a stand. Some mobile device stands are not very compact or easily portable.

Furthermore, when a person is on an aircraft and wishes to watch content on their mobile device hands free, the person can use a stand to hold their mobile device on the aircraft tray table. However, the stand and mobile device can easily fall off the tray table due to aircraft vibrations and turbulence.

The present invention seeks to provide a holder for an electronic device, which will overcome or substantially ameliorate at least some of the deficiencies of the prior art, or to at least provide an alternative.

It is to be understood that, if any prior art information is referred to herein, such reference does not constitute an admission that the information forms part of the common general knowledge in the art, in Australia or any other country.

The preceding discussion of background art is intended to facilitate an understanding of the present invention only. The discussion is not an acknowledgement or admission that any of the material referred to is or was part of the common general knowledge as at the priority date of the application.

### SUMMARY OF INVENTION

It is an object of the embodiments described herein to overcome or alleviate at least one of the above noted drawbacks of related art systems or to at least provide a useful alternative to related art systems.

Disclosed herein is a holder for an electronic or like device, configured to move between a closed position and an open position, the holder including:
a first resiliently deformable member including a first end and a second end;
a second resiliently deformable member including a first end and a second end, the second resiliently deformable member being connected to the first resiliently deformable member at the respective first ends; and
a first engaging formation connected to the second end of the first resiliently deformable member;
a second engaging formation connected to the second end of the second resiliently deformable member,
wherein, in the closed position, the first resiliently deformable member and the second resiliently deformable member are coplanar, and
wherein in the open position, the second end of the first resiliently deformable member and the second end of the second resiliently deformable member are disposed away from each other to hold an electronic device between the engaging formations of the first resiliently deformable member and the second resiliently deformable member, when in use.

Advantageously, because the first resiliently deformable member and the second resiliently deformable member are coplanar, the thickness of the device holder is minimised.

Advantageously, because the thickness of the device holder is minimised in the closed position, the device holder is readily portable.

In one embodiment, when in the open position, the first resiliently deformable member and the second resiliently deformable member deflect to accommodate the electronic device between the engaging formations.

In one embodiment, the deflection of the first resiliently deformable member and the second resiliently deformable member provides a gripping force to hold the electronic device between the engaging formations.

Advantageously, the device holder can adequately grip an electronic device between the first and second resiliently deformable members, due to the force exerted by the first and second resiliently deformable members on the electronic device.

In one embodiment, first resiliently deformable member is integrally formed with the second resiliently deformable member.

In one embodiment, the first engaging formation is integrally formed with the first resiliently deformable member and second engaging formation is integrally formed with the second resiliently deformable member.

Advantageously, due to the first and second resiliently deformable members being integrally formed, the device holder is simple to manufacture. Accordingly, fewer parts are required to manufacture the device holder.

In one embodiment, the first engaging formation includes an end region of the second end of the first resiliently deformable member and a first tab integrally formed with the end region of the first resiliently deformable member.

In one embodiment, the second engaging formation includes at an end region of the second end of the second resiliently deformable member a second tab integrally formed with the end region of the second resiliently deformable member.

In one embodiment, the first tab is configured to deflect relative to the first resiliently deformable member and the second tab is configured to deflect relative to the second resiliently deformable member, such that, in use, at least a portion of one side of the electronic device is engaged between the end region of the second end of the first resiliently deformable member and the first tab and at least a portion of an opposite side of the electronic device is engaged between an end region of the second end of the second resiliently deformable member and the second tab.

In one embodiment, the first end of the first resiliently deformable member defines a first foot and the second end of the second resiliently deformable member defines a second foot, such that in use, when the device holder is in the open position, the first foot and the second foot support the device holder and the electronic device when the device holder is placed on a surface.

Advantageously, the first foot is part of the first and second resiliently deformable members which provides simple and thin integration of parts. Accordingly, fewer parts are required and thickness of the device holder is minimised.

In one embodiment, the first resiliently deformable member and the first tab define an acute angle to engage at least a portion of one side of the electronic device therebetween, when in use.

In one embodiment, the second resiliently deformable member and the second tab define an acute angle to engage at least a portion of the opposite side of the electronic device therebetween, when in use.

In one embodiment, the device holder further includes a third member connected to the first resiliently deformable member, the third member including a mounting region configured for hanging the device holder from a formation.

Advantageously, the mounting region allows a user to hang the device holder from the formation.

In one embodiment, the mounting region is an aperture.

In one embodiment, the third member is resiliently deformable.

In one embodiment, the third member includes a backing region which is connected to the first resiliently deformable member to provide a rear outer of the device holder. In an alternative embodiment, the third member is integrally formed with the second end of the first resiliently deformable member.

In one embodiment, the third member extends beyond the second end of the first resiliently deformable member to provide a front outer that is pivotal about the second end of the first resiliently deformable member.

In one embodiment, the front outer is pivotal to sandwich the first resiliently deformable member and the second resiliently deformable member between the front outer and the rear outer.

In one embodiment, the front outer includes the aperture for mounting the device holder from a formation.

In one embodiment, one or more selected from the first resiliently deformable member, the second resiliently deformable member, and the third member is configured for displaying usage instructions and/or advertising graphics.

This invention may also be said broadly to comprise the parts, elements and features referred to or indicated in the specification of the application, individually or collectively, and any or all combinations of any two or more of said parts, elements or features, and where specific integers are mentioned herein which have known equivalents in the art to which this invention relates, such known equivalents are deemed to be incorporated herein as if individually set forth.

To those skilled in the art to which the invention relates, many changes in construction and widely differing embodiments and applications of the invention will suggest themselves without departing from the scope of the invention as defined in the appended claims. The disclosures and the descriptions herein are purely illustrative and are not intended to be in any sense limiting.

Other aspects and preferred forms are disclosed in the specification and/or defined in the appended claims, forming a part of the description of the invention.

In essence, embodiments of the present invention stem from the realization that not only is it necessary to provide physical support for a smartphone or like device when using that device in a travelling vehicle, it is also desirable that the support to be able to hold the device relatively firmly to prevent escape of the device from the holder.

Advantages provided by the present invention comprise the following:
The electronic device can be relatively firmly retained in the holder.
The holder is light weight and is foldable to facilitate storage of it when it is not in use.
It allows users to watch content on their mobile device without the need to hand-hold the mobile device.
In aircraft or other vehicles, the user can place the holder (with mobile device inserted) on the aircraft tray table or suspend them from hooks or the like.

Further scope of applicability of embodiments of the present invention will become apparent from the detailed description given hereinafter. However, it should be understood that the detailed description and specific examples, while indicating preferred embodiments of the invention, are given by way of illustration only, since various changes and modifications within the spirit and scope of the disclosure herein will become apparent to those skilled in the art from this detailed description.

### BRIEF DESCRIPTION OF THE DRAWINGS

Further disclosure, objects, advantages and aspects of preferred and other embodiments of the present invention may be better understood by those skilled in the relevant art by reference to the following description of embodiments taken in conjunction with the accompanying drawings, which are given by way of illustration only, and thus are not limitative of the disclosure herein, and in which:

FIG. 1 shows an isometric view of a holder for an electronic device according to a first embodiment, when the device holder is in a closed position;

FIG. 2 shows a top view of the device holder shown in FIG. 1;

FIG. 3 shows a bottom view of the device holder shown in FIG. 1;

FIG. 4 shows a front view of the device holder shown in FIG. 1;

FIG. 5 shows a rear view of the device holder shown in FIG. 1;

FIG. 6 shows a left side view of the device holder shown in FIG. 1;

FIG. 7 shows a right side view of the device holder shown in FIG. 1;

FIG. 8 shows an isometric view of the device holder shown in FIG. 1, when the device holder is in a partially open position;

FIG. 9 shows a front view of the device holder shown in FIG. 8;

FIG. 10 shows a rear view of the device holder shown in FIG. 8;

FIG. 11 shows a top view of the device holder shown in FIG. 8;

FIG. 12 shows a bottom view of the device holder shown in FIG. 8;

FIG. 13 shows a left side view of the device holder shown in FIG. 8;

FIG. 14 shows a right side view of the device holder shown in FIG. 8;

FIG. 15 shows an isometric view of the device holder shown in FIGS. 1 to 14, between the open and closed positions;

FIG. 16 shows an isometric view of the device holder shown in FIG. 15, between the open and closed positions;

FIG. 17 shows an isometric view of the device holder shown in FIG. 15, in an open position;

FIG. 18 shows an isometric view of the device holder in an open position when holding a mobile device;

FIG. 19 shows an environmental view of the device holder shown in FIGS. 1 to 18 when suspended from the back of an aircraft seat;

FIG. 20 shows another environmental view of the device holder shown in FIG. 19 when the device holder is placed on a surface; and

FIG. 21 shows another environmental view of the device holder shown in FIG. 19 when the device holder is placed on a surface.

FIG. 22 shows a top view of a holder for an electronic device according to a second embodiment, when the device holder is in a closed position;

FIG. 23 shows an isometric view of the device holder shown in FIG. 22, when the device holder is in an open position;

FIG. 24 shows an isometric view of the device holder shown in FIG. 22, when the device holder is in an open position and holding a mobile device; and

FIG. 25 shows an environmental view of the device holder shown in FIGS. 22 to 24, when suspended from the back of an aircraft seat.

### DETAILED DESCRIPTION

It should be noted in the following description that like or the same reference numerals in different embodiments denote the same or similar features.

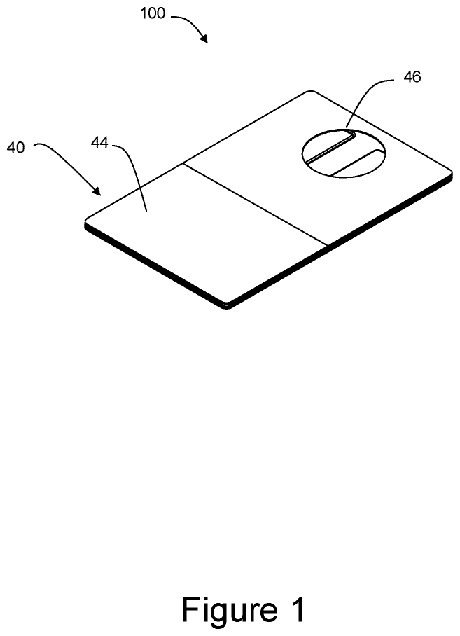

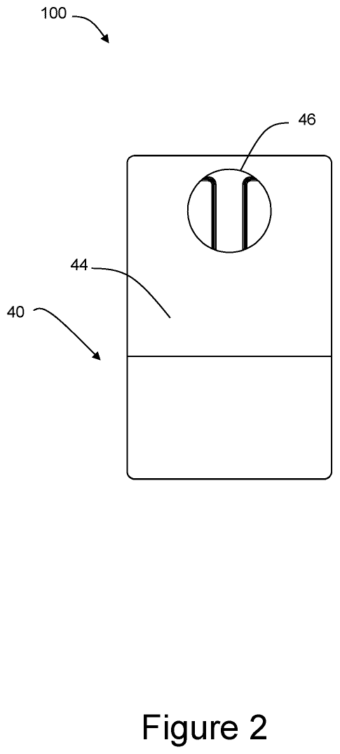

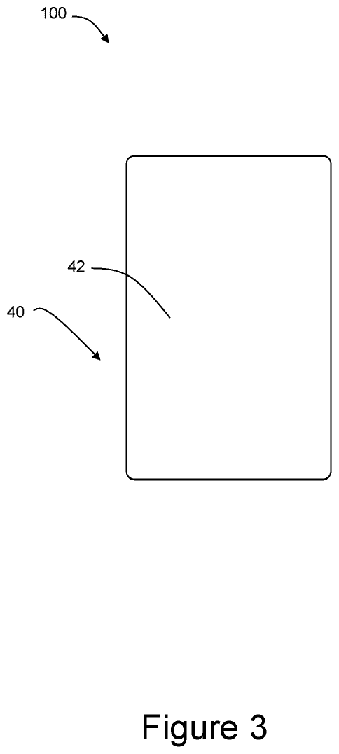

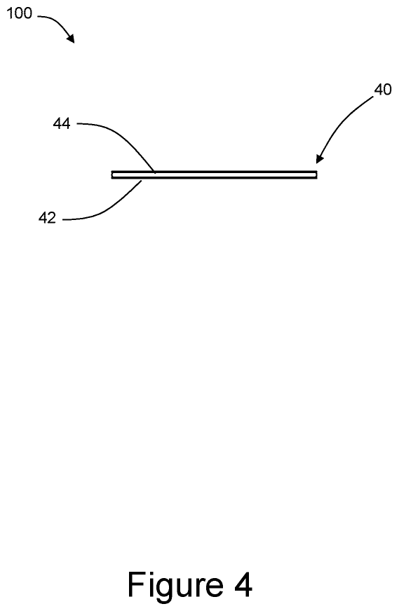

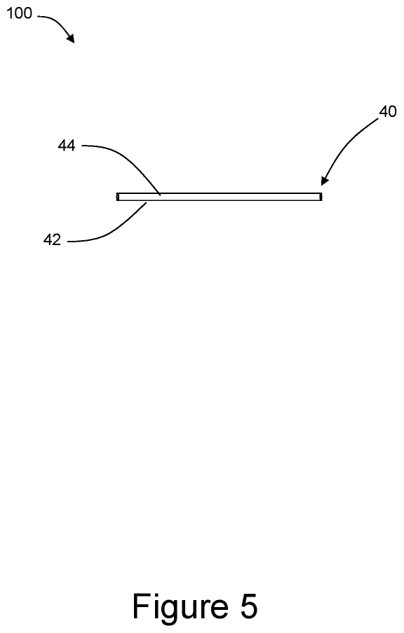

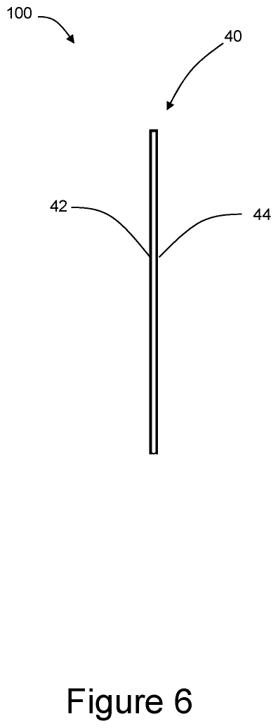

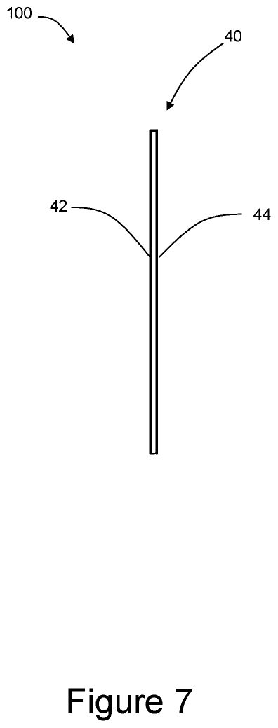

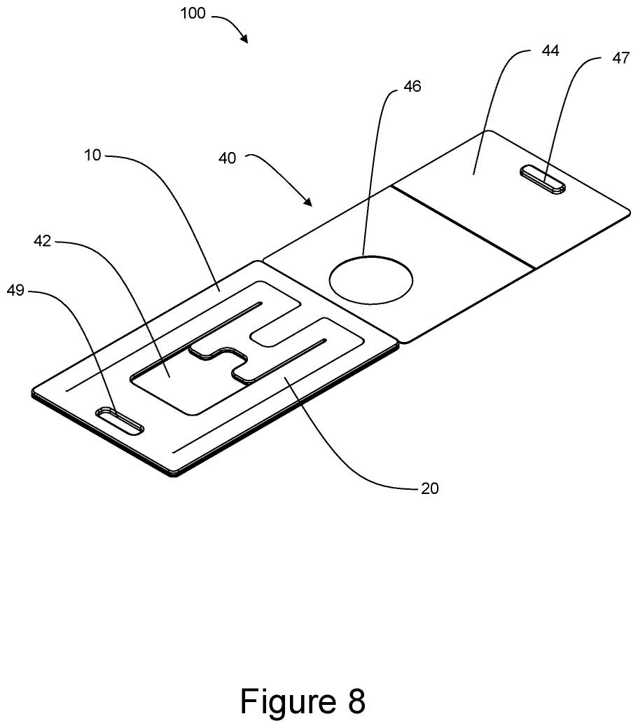

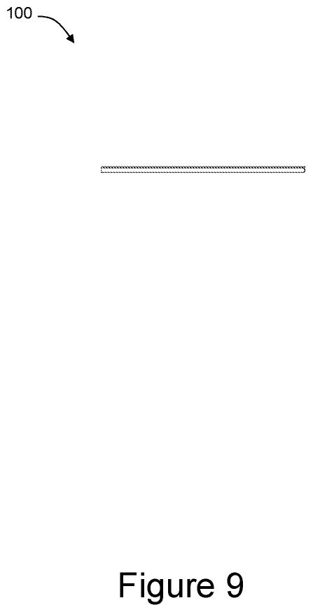

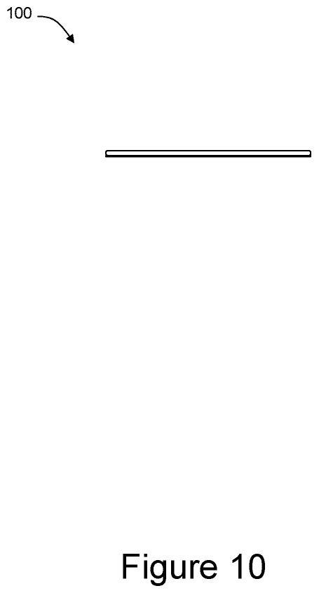

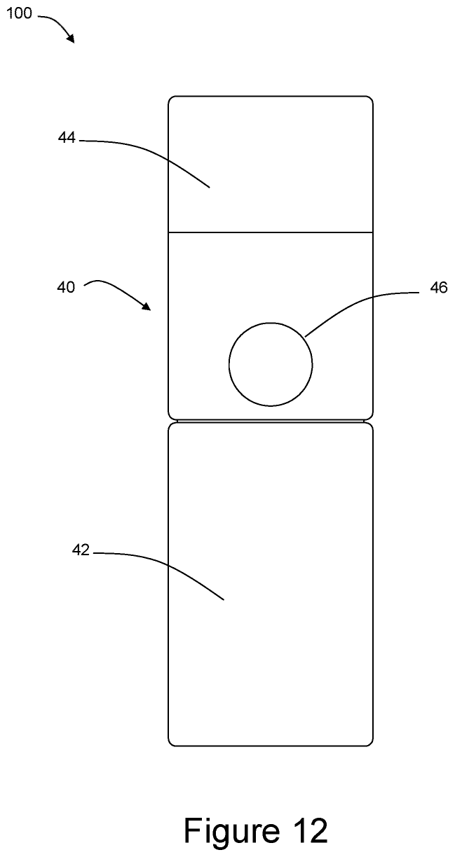

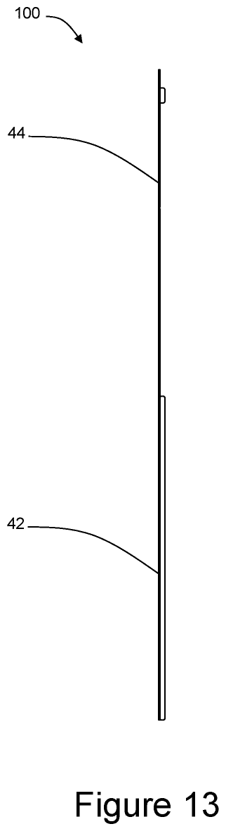

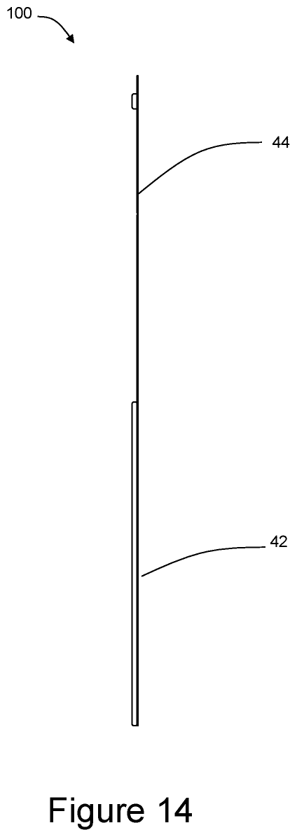

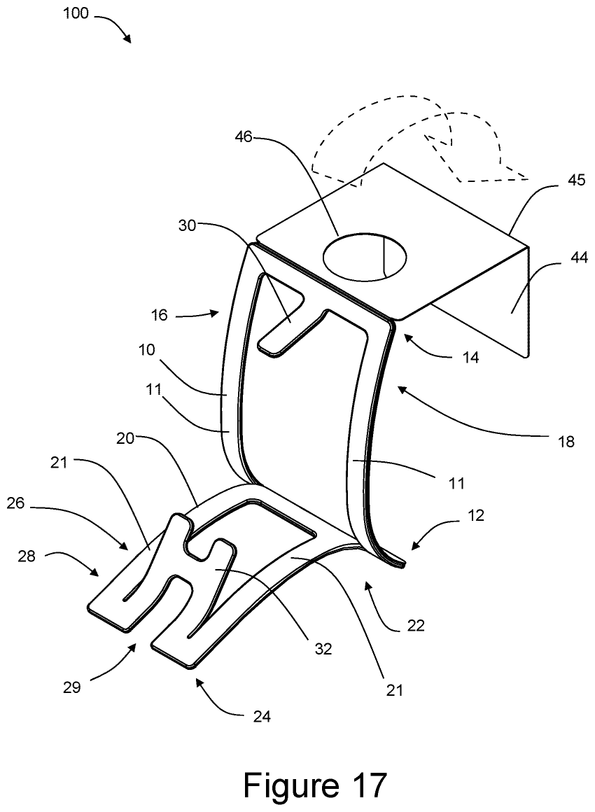

FIGS. 1 to 21 show a holder 100 for an electronic device, according to a first embodiment, that is configured to move between a closed position and an open position. FIGS. 1 to 7 show the device holder 100 in a fully closed position. In the fully closed position, the device holder is sized such that it can be inserted into a card holder (not shown) or a wallet (not shown). FIGS. 8 to 16 show the device holder in a partially open position. FIGS. 17 to 21 show the device holder 100 in a fully open position while holding an electronic device 200. The electronic device can be a mobile phone, tablet or the like.

The device holder 100 as shown in FIG. 17 includes a first resiliently deformable member 10 which includes a first end 12 and a second end 14. The device holder 100 also includes a second resiliently deformable member 20 which includes a first end 22 and a second end 24. The second resiliently deformable member 20 is connected to the first resiliently deformable member 10 at their respective first ends 12, 22. In the embodiment shown, the first resiliently deformable member 10 and the second resiliently deformable member 20 are integrally formed at their respective first ends 12, 22.

The device holder 100 further includes a first engaging formation 16 connected to the second end 14 of the first resiliently deformable member 10. There is also a corresponding second engaging formation 26 connected to the second end 24 of the second resiliently deformable member 20. Best seen in FIGS. 1 to 7, in the closed position, the first resiliently deformable member 10 and the second resiliently deformable member 20 are coplanar so that the device holder 100 can be flattened to fit into a card holder (not shown) or a wallet (not shown). Best seen in FIG. 17, in the open position, the second end 14 of the first resiliently deformable member 10 and the second end 24 of the second resiliently deformable member 20 are disposed away from each other to hold the electronic device 200 between the engaging formations 16, 26 of the first resilient deformable member 10 and the second resiliently deformable member 20, when in use.

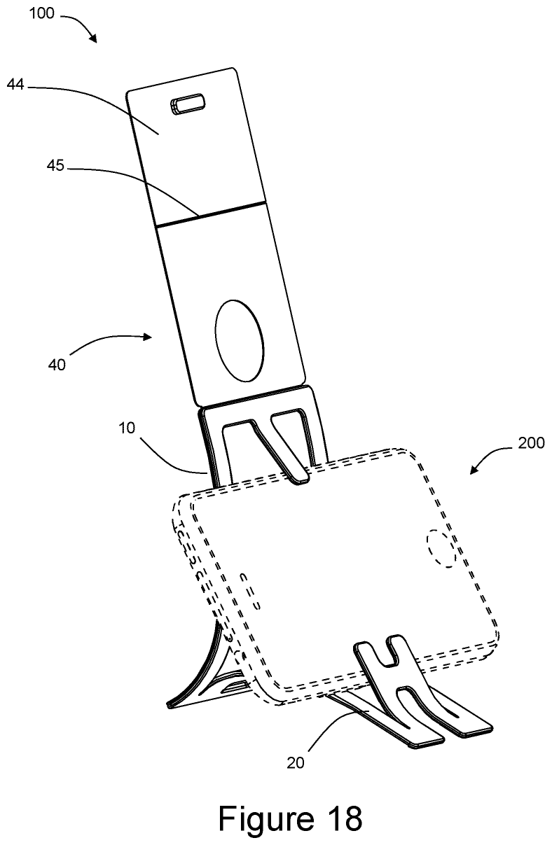

As shown in at least FIGS. 17 and 18, the first resiliently deformable member 10 and the second resiliently deformable member 20 deflect to accommodate the electronic device 200 between the engaging formations 16, 26. The first resiliently deformable member 10 and the second resiliently deformable member 20 deflect near their respective first ends 12, 22, which are integrally formed. The first resiliently deformable member 10 and the second resiliently deformable member 20 also deflect or bend throughout their lengths. This deflection or bending of the resiliently deformable members 10, 20 provides a gripping force to hold the electronic device 200 in position. The first engaging formation 16 includes an end region 18 at the second end 14 of the first resiliently deformable member 10 and a first tab 30 that is integrally formed with the end region 18 of the first resiliently deformable member 10. The first resiliently deformable member 10 includes two pillars 11 which extend from the first end 12 to the second end 14. A portion of the pillars 11 include a cross-piece that forms part of the end region 18, which in turn forms the first tab 30.

The second engaging formation 26 includes an end region 28 of the second end 24 of the second resiliently deformable member 20 and a second tab 32 that is integrally formed with the end region 28 of the second resiliently deformable member 20. The second resiliently deformable member 20 includes two pillars 21 which extend from the first end 22 to the second end 24. A portion of the pillars 21 include a complementary cross piece section that forms part of the end region 28, which in turn, forms the second tab 32. The cross piece of the pillar 11 is formed to fit snugly together with the complementary cross piece section of the pillar 21. Such that they are coplanar with each other when the device is in the closed position.

As shown in FIGS. 18 to 21, the electronic device 200 can be placed in the device holder 100, whereby the first tab 30 is configured to deflect relative to the first resiliently deformable member 10 and the second tab 32 is configured to deflect relative to the second resiliently deformable member 20. In this way, at least a portion of one side of the electronic device 200 is engaged between the end region 18 of the second end 14 of the first resiliently deformable member 10 and the first tab 30, and at least a portion of an opposite side of the electronic device 200 is engaged between an end region 28 of the second end 24 of the second resiliently deformable member 20 and the second tab 32. The second end region 28 also includes a notch or a cut out 29, which serves to accept the tab 30, when the device holder 100 is in the closed position, or when the first resiliently deformable member 10 and the second resiliently deformable member 20 are in a coplanar position with each other.

It can be seen that when the tabs 30, 32 deflect to accommodate the electronic device 200, another holding force is provided on the electronic device 200 between the tabs 30, 32 and the respective end regions 18, 28 of the first and second resiliently deformable members 10, 20. When deflected, the first tab 30 forms an acute angle with the first resiliently deformable member 10 and the second tab 32 forms an acute angle with the second resiliently deformable member 20. At least a portion of the tabs 30, 32 sit over a front face of the electronic device 200, as shown in FIG. 18. At least a portion of the pillars 11, 21 support a rear edge or back of the electronic device 200, as shown in FIG. 18.

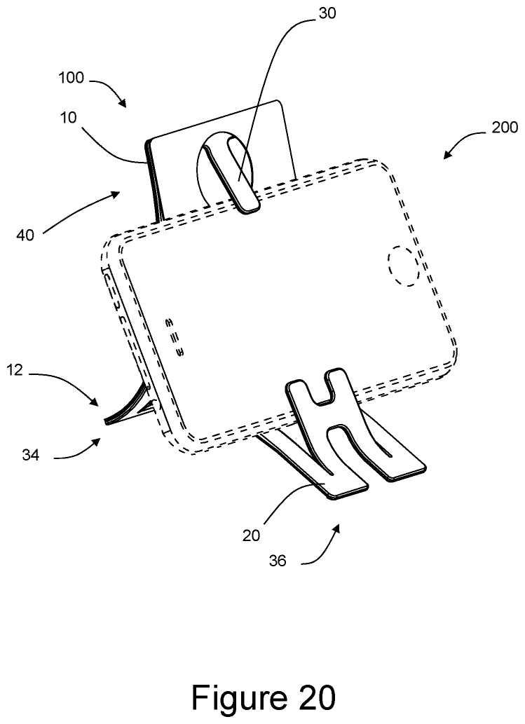

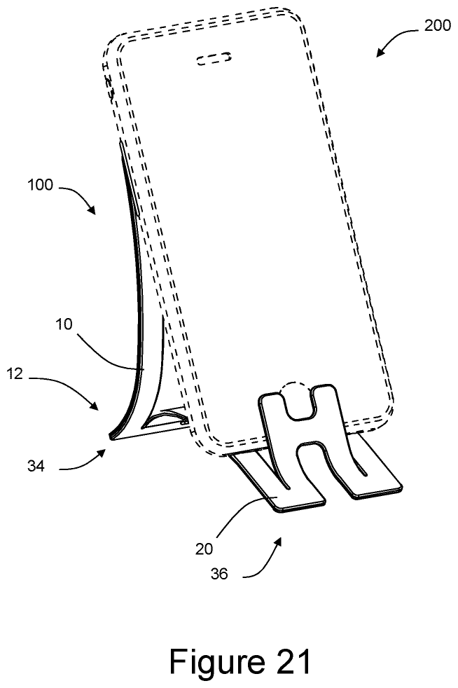

In FIGS. 20 and 21, it is also shown that the first end 12 of the first resiliently deformable member 10 defines a first foot 34 and the second end 24 second resiliently deformable member 20 defines a second foot 36. The first foot 34 and the second foot 36 support the device holder 100 and the electronic device 200 held therein, when the device holder 100 is placed on a surface.

In FIG. 21, it is shown that the first tab 30 does not necessarily need to deflect to grip the mobile device 200. In FIG. 21, the mobile device 200 is orientated in a portrait configuration relative to the device holder 100, meaning that the mobile device 200 is too tall for the device holder 100. In this configuration, the mobile device 200 can still be gripped by the second tab 32 and supported from the rear by the first resiliently deformable member 10.

Turning back to FIGS. 8 and 15 to 19, the device holder 100 also includes a third member 40 connected to the first resiliently deformable member 10. In the embodiment shown, the third member 40 has a backing region 42 that is connected to the first resiliently deformable member 10 to provide a rear outer of the device holder 100. The third member 40 may also be resiliently deformable such that it can deform together with the first resiliently deformable member. The backing region 42 can be adhered to the first resiliently deformable member 10 using a suitable plastic glue, or the third member 40 can be plastic welded to the first resiliently deformable member 10 at the backing region 42.

According to embodiments of the invention which are not illustrated in the drawings, the third member is integrally formed with the second end of the first resiliently deformable member.

The third member 40 extends beyond the second end 14 of the first resiliently deformable member 10 to provide a front outer 44 (or a front outer portion 44). The front outer 44 is connected to the rear outer 42 (or a rear outer portion 42) such that they are integrally formed. The front outer 44 and the rear outer 42 bend so that the front outer 44 pivots about the second end 14 of the first resiliently deformable member 10. The front outer 44 can pivot to sandwich the first resiliently deformable member 10 and the second resiliently deformable 20 member between the front outer 44 and the rear outer 42, as shown in FIG. 1.

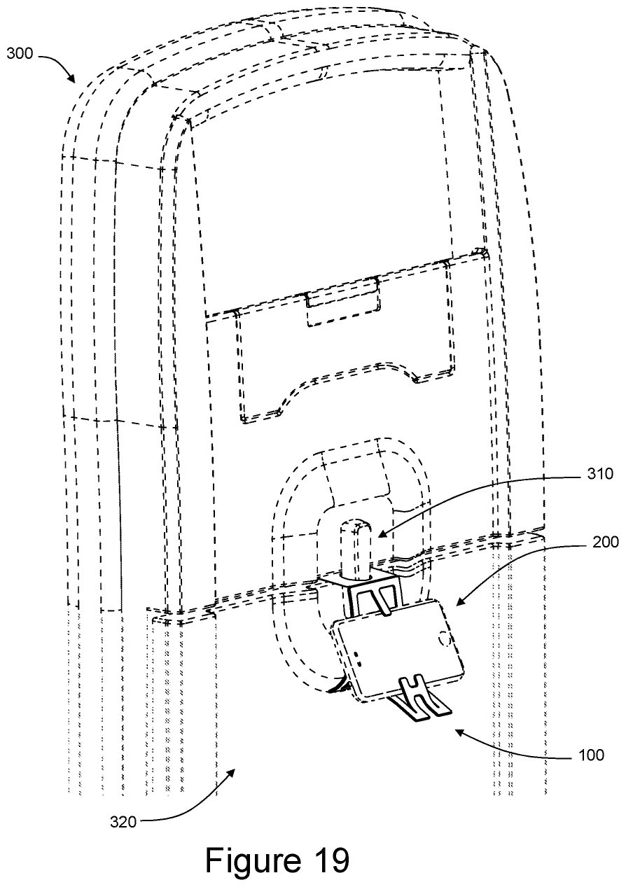

The third member 40, further includes an aperture 46 in the front outer 44. As shown in the environmental view in FIG. 19, the aperture 46 can be used for mounting the electronic device from a formation such as a hook 310 on the back of an aircraft seat 300. The hook 310 is normally used for retaining a tray table 320 connected to the back of the aircraft seat 300 in an upright position. The front outer 44 also includes a fold line or crease 45. The fold line 45 indicates to a user, where to fold the outer 44 so that a portion of the front outer 44 can fit behind the tray table 320, when the device holder 100 is in use.

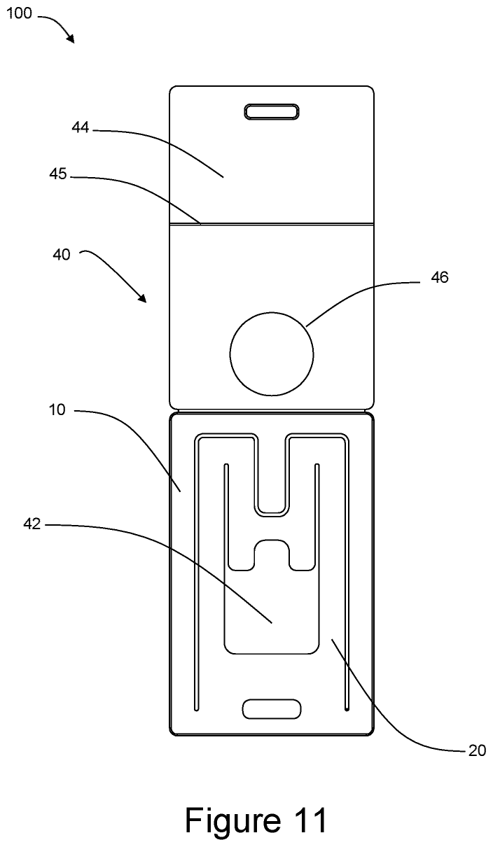

Also included, and best shown in FIGS. 8 and 11, is a projection 47 and an aperture 49. The projection 47 is located on the front outer 44 of the third member 40. The aperture 49 is located at the first end 22 of the second resiliently deformable member 20. The projection 47 is configured to engage with the aperture 49 to retain the third member 40 such that the device holder 100 can remain in a closed position. The projection 47 snap-fits into the aperture 49 for simple and quick engagement.

In one embodiment, the first resiliently deformable member 10 and the second resiliently deformable member 20 is made from a polymer that is about 1 mm to 2 mm in thickness. In one embodiment, the third member 40 is made from a polymer that is about 0.2 mm to 0.5 mm in thickness. These thicknesses of the members 10, 20, 40 allow the device holder to fit in a credit card holder or wallet, when in the closed position. The third member 40 is thinner than the first resiliently deformable member 10 and the second resiliently deformable member 20 to allow the third member 40 to bend around the first resiliently deformable member 10 and the second resiliently deformable member 20, when the device holder 100 is in the closed position.

In an alternative embodiment, the material of the first resiliently deformable member 10 and the second resiliently deformable member 20 may be thicker to provide a holder for an electronic device that is larger, more durable and/or capable of holding larger devices such as a tablet.

It is also envisaged that the first resiliently deformable member 10 and the second resiliently deformable member 20 can be made from metal, to allow the device holder to be more durable. The third member 40 may also be made from metal.

It is further envisaged that the first resiliently deformable member 10, the second resiliently deformable member 20 and/or the third member 40 can be used to print graphics for advertising and/or instructions for unfolding the device holder. Any one or combination of the members 10, 20, 40 can be used to print graphics for advertising and/or instructions for unfolding the device holder.

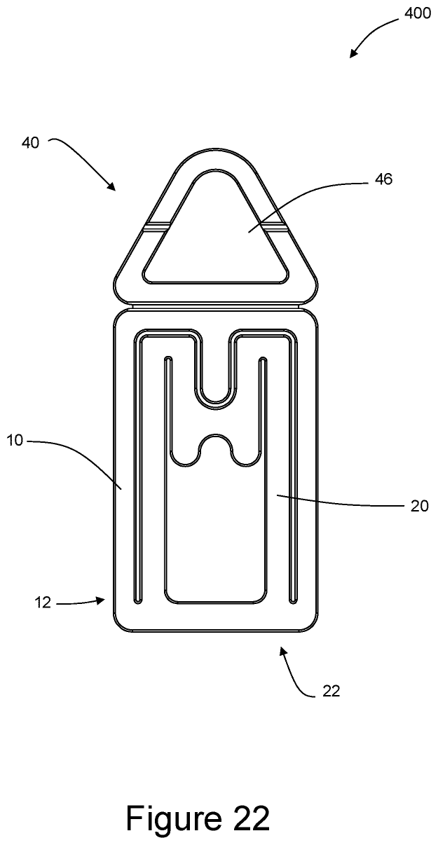

FIGS. 22 to 25 show a holder 400 for an electronic device according to a second embodiment in a closed position. The device holder 400 is similar to the device holder 100, hence like terms and numbering of parts have been used. The device holder 400 has the same first resiliently deformable member 10 that is connected to the second resiliently deformable member 20 at their respective first ends 12, 22.

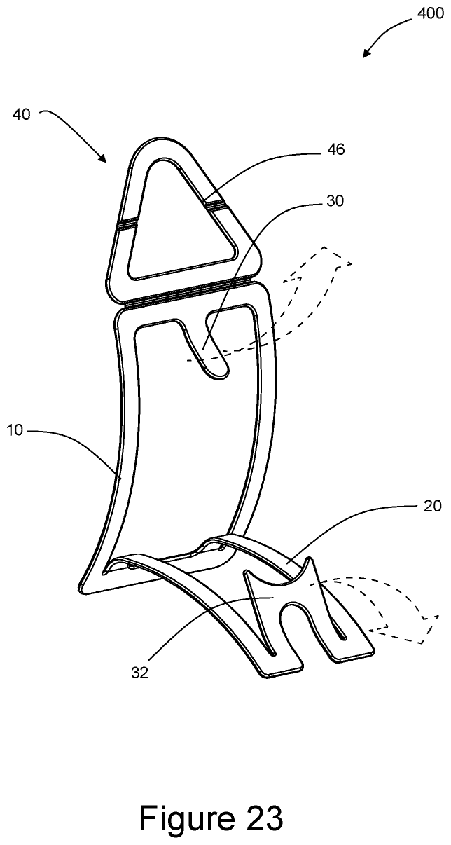

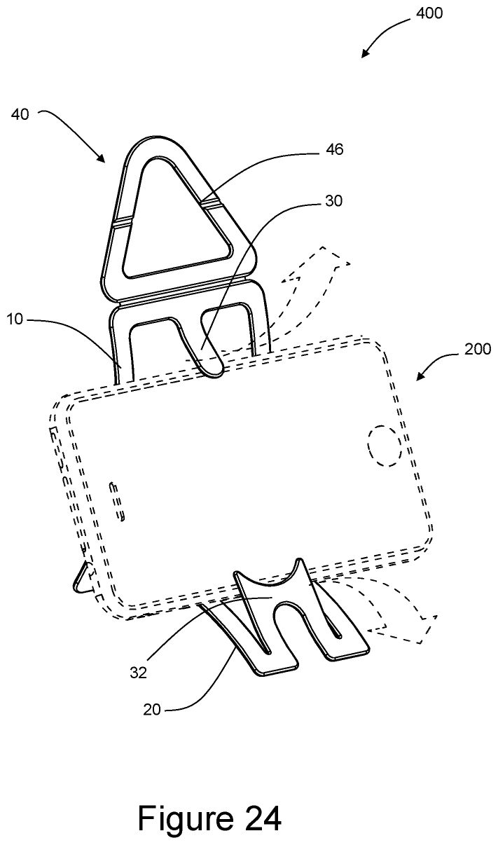

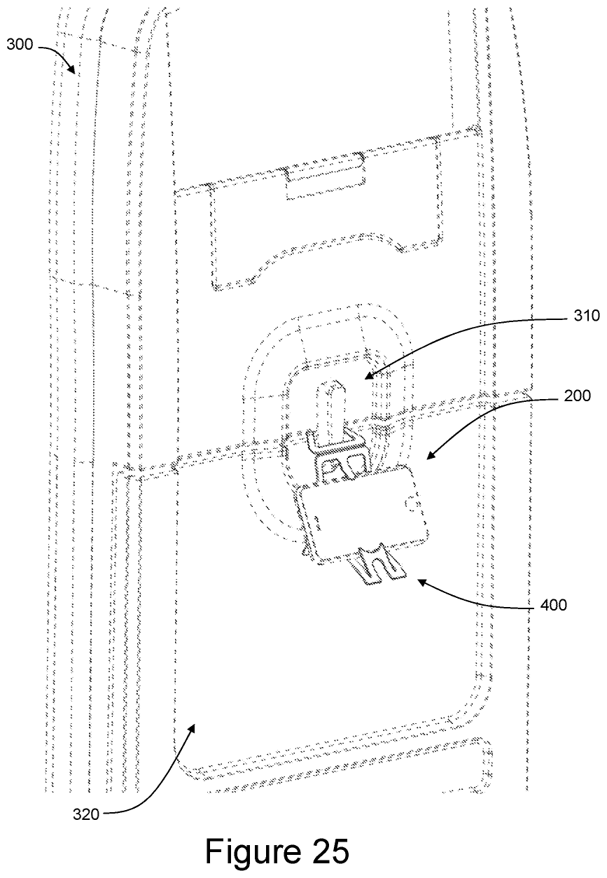

As shown in FIGS. 23 and 24, the device holder 400 has the same tabs 30 and 32 connected to the respective first resiliently deformable member 10 and second resiliently deformable member 20. The tabs 30, 32 operate in the same way as the tabs of the first embodiment 100. However, rather than having a third member 40 that covers the first resiliently deformable member 10 and the second resiliently deformable member 20, a triangularly shaped third member 40 is provided. The third member 40 defines a triangularly shaped aperture 46 and is connected to the first resiliently deformable member 10 and is able to rotate relative to the first resiliently deformable member 10 and the second resiliently deformable member 20. The triangular third member 40 can be made thicker and sturdier than the resiliently deformable members 10, 20 and as shown in FIG. 25, can be hung from the back of the aircraft seat 300 at the hook 310.

Use of the device holder 100 will now be described.

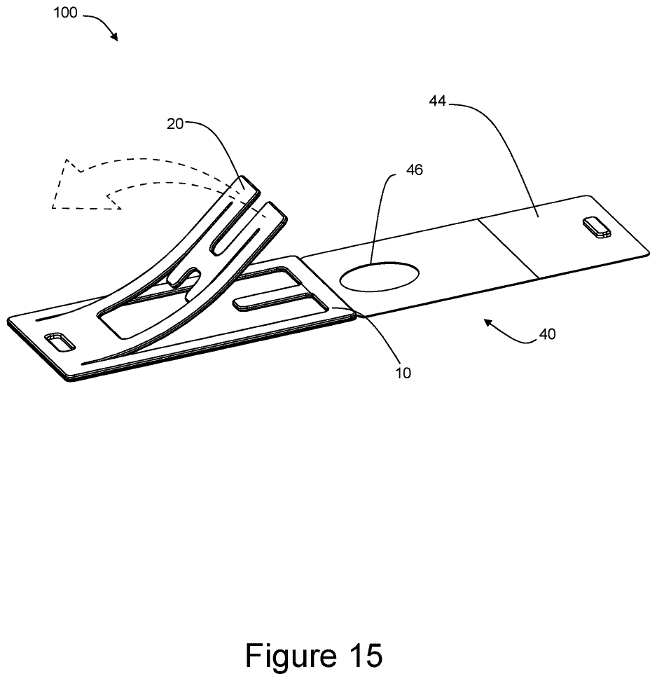

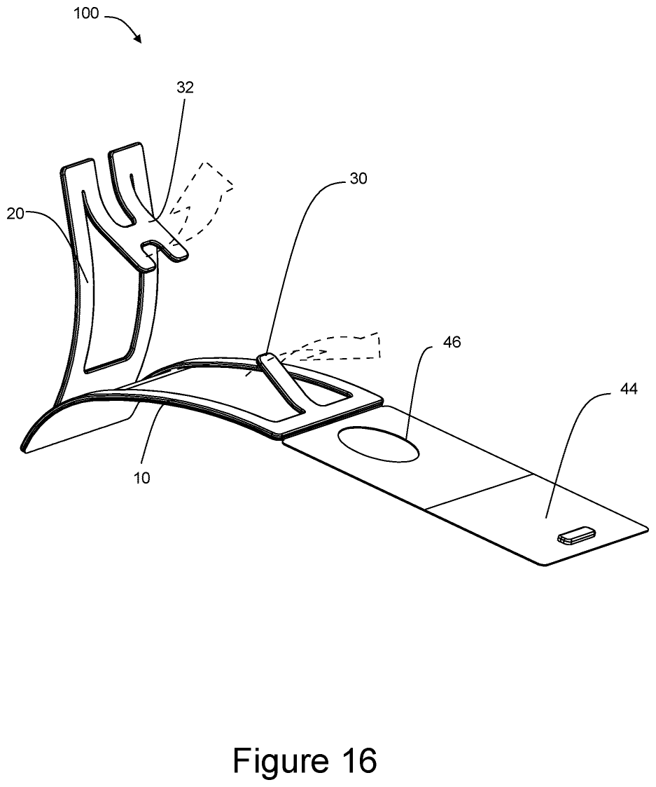

Starting from the closed position, the user can move the third member 40 and open the front outer 44 by disengaging the projection 47 from the aperture 49 from the position shown in FIG. 1 to the position shown in FIG. 8. The user can then move the second resiliently deformable member 20 away from the coplanar position with the first resiliently deformable member 10, as shown in FIG. 15. The user then bends the first tab 30 and the second tab 32 as shown in FIG. 16. At this point, the user may also bend the front outer 44 at crease 45 as shown in FIG. 17. The user then places a portion of the side of their electronic device between the first resiliently deformable member 10 and the first tab 30, and the opposite portion of the side of their electronic device between the second resiliently deformable member 20 and the second tab 32, as shown in FIG. 18. The user can then tuck the outer 44 behind the tray table 320 and use the aperture 46 to hang the device holder 100 from the hook 310, as shown in FIG. 19. Alternatively, only the outer 44 is tucked behind the tray table 320 at any point along an edge of the tray table 320 without using the aperture 46 to hang the device holder. In this way, it is envisaged that the force between the edge of the tray table 320 and the back of the aircraft seat 300 will retain the device holder 100 and the electronic device 200 in place. Alternatively, the third member 40 and outer 44 may not be used and the device holder can be placed on a table or surface as shown in FIG. 20 and FIG. 21, supported on foot 34 and foot 36.

It is envisaged that the device holder can be sized to accept larger devices such as a tablet.

While this invention has been described in connection with specific embodiments thereof, it will be understood that it is capable of further modification(s). This application is intended to cover any variations uses or adaptations of the invention following in general, the principles of the invention and including such departures from the present disclosure as come within known or customary practice within the art to which the invention pertains and as may be applied to the essential features hereinbefore set forth.

As the present invention may be embodied in several forms without departing from the spirit of the essential characteristics of the invention, it should be understood that the above described embodiments are not to limit the present invention unless otherwise specified, but rather should be construed broadly within the spirit and scope of the invention as defined in the appended claims. The described embodiments are to be considered in all respects as illustrative only and not restrictive.

Various modifications and equivalent arrangements are intended to be included within the spirit and scope of the invention and appended claims. Therefore, the specific embodiments are to be understood to be illustrative of the many ways in which the principles of the present invention may be practiced. In the following claims, any means-plus-function clauses are intended to cover structures as performing the defined function and not only structural equivalents, but also equivalent structures. For example, although a nail and a screw may not be structural equivalents in that a nail employs a cylindrical surface to secure wooden parts together, whereas a screw employs a helical surface to secure wooden parts together, in the environment of fastening wooden parts, a nail and a screw are equivalent structures.

### Industrial Applicability

It is apparent from the above, that the arrangements described are applicable to the consumer products industries.

The following sections I-V provide a guide to interpreting the present specification.

### I. Terms

The term “product” means any machine, manufacture and/or composition of matter, unless expressly specified otherwise.

The term “process” means any process, algorithm, method or the like, unless expressly specified otherwise.

Each process (whether called a method, algorithm or otherwise) inherently includes one or more steps, and therefore all references to a “step” or “steps” of a process have an inherent antecedent basis in the mere recitation of the term ‘process’ or a like term. Accordingly, any reference in a claim to a ‘step’ or ‘steps’ of a process has sufficient antecedent basis.

The term “invention” and the like mean “the one or more inventions disclosed in this specification”, unless expressly specified otherwise.

The terms “an embodiment”, “embodiment”, “embodiments”, “the embodiment”, “the embodiments”, “one or more embodiments”, “some embodiments”, “certain embodiments”, “one embodiment”, “another embodiment” and the like mean “one or more (but not all) embodiments of the disclosed invention(s)”, unless expressly specified otherwise.

The term “variation” of an invention means an embodiment of the invention, unless expressly specified otherwise.

A reference to “another embodiment” in describing an embodiment does not imply that the referenced embodiment is mutually exclusive with another embodiment (e.g., an embodiment described before the referenced embodiment), unless expressly specified otherwise.

The terms “including”, “comprising” and variations thereof mean “including but not limited to”, unless expressly specified otherwise.

The terms “a”, “an” and “the” mean “one or more”, unless expressly specified otherwise.

The term “plurality” means “two or more”, unless expressly specified otherwise.

The term “herein” means “in the present specification, including anything which may be incorporated by reference”, unless expressly specified otherwise.

The phrase “at least one of”, when such phrase modifies a plurality of things (such as an enumerated list of things), means any combination of one or more of those things, unless expressly specified otherwise. For example, the phrase “at least one of a widget, a car and a wheel” means either (i) a widget, (ii) a car, (iii) a wheel, (iv) a widget and a car, (v) a widget and a wheel, (vi) a car and a wheel, or (vii) a widget, a car and a wheel. The phrase “at least one of”, when such phrase modifies a plurality of things, does not mean “one of each of” the plurality of things.

Numerical terms such as “one”, “two”, etc. when used as cardinal numbers to indicate quantity of something (e.g., one widget, two widgets), mean the quantity indicated by that numerical term, but do not mean at least the quantity indicated by that numerical term. For example, the phrase “one widget” does not mean “at least one widget”, and therefore the phrase “one widget” does not cover, e.g., two widgets.

The phrase “based on” does not mean “based only on”, unless expressly specified otherwise. In other words, the phrase “based on” describes both “based only on” and “based at least on”. The phrase “based at least on” is equivalent to the phrase “based at least in part on”.

The term “represent” and like terms are not exclusive, unless expressly specified otherwise. For example, the term “represents” do not mean “represents only”, unless expressly specified otherwise. In other words, the phrase “the data represents a credit card number” describes both “the data represents only a credit card number” and “the data represents a credit card number and the data also represents something else”.

The term “whereby” is used herein only to precede a clause or other set of words that express only the intended result, objective or consequence of something that is previously and explicitly recited. Thus, when the term “whereby” is used in a claim, the clause or other words that the term “whereby” modifies do not establish specific further limitations of the claim or otherwise restricts the meaning or scope of the claim.

The term “e.g.” and like terms mean “for example”, and thus does not limit the term or phrase it explains. For example, in the sentence “the computer sends data (e.g., instructions, a data structure) over the Internet”, the term “e.g.” explains that “instructions” are an example of “data” that the computer may send over the Internet, and also explains that “a data structure” is an example of “data” that the computer may send over the Internet. However, both “instructions” and “a data structure” are merely examples of “data”, and other things besides “instructions” and “a data structure” can be “data”.

The term “i.e.” and like terms mean “that is”, and thus limits the term or phrase it explains. For example, in the sentence “the computer sends data (i.e., instructions) over the Internet”, the term “i.e.” explains that “instructions” are the “data” that the computer sends over the Internet.

Any given numerical range shall include whole and fractions of numbers within the range. For example, the range “1 to 10” shall be interpreted to specifically include whole numbers between 1 and 10 (e.g., 2, 3, 4, . . . 9) and non-whole numbers (e.g., 1.1, 1.2, . . . 1.9).

### II. Determining

The term “determining” and grammatical variants thereof (e.g., to determine a price, determining a value, determine an object which meets a certain criterion) is used in an extremely broad sense. The term “determining” encompasses a wide variety of actions and therefore “determining” can include calculating, computing, processing, deriving, investigating, looking up (e.g., looking up in a table, a database or another data structure), ascertaining and the like. Also, “determining” can include receiving (e.g., receiving information), accessing (e.g., accessing data in a memory) and the like. Also, “determining” can include resolving, selecting, choosing, establishing, and the like.

The term “determining” does not imply certainty or absolute precision, and therefore “determining” can include estimating, extrapolating, predicting, guessing and the like.

The term “determining” does not imply that mathematical processing must be performed, and does not imply that numerical methods must be used, and does not imply that an algorithm or process is used.

The term “determining” does not imply that any particular device must be used. For example, a computer need not necessarily perform the determining.

### III. Indication

The term “indication” is used in an extremely broad sense. The term “indication” may, among other things, encompass a sign, symptom, or token of something else.

The term “indication” may be used to refer to any indicia and/or other information indicative of or associated with a subject, item, entity, and/or other object and/or idea.

As used herein, the phrases “information indicative of” and “indicia” may be used to refer to any information that represents, describes, and/or is otherwise associated with a related entity, subject, or object.

Indicia of information may include, for example, a symbol, a code, a reference, a link, a signal, an identifier, and/or any combination thereof and/or any other informative representation associated with the information.

In some embodiments, indicia of information (or indicative of the information) may be or include the information itself and/or any portion or component of the information. In some embodiments, an indication may include a request, a solicitation, a broadcast, and/or any other form of information gathering and/or dissemination.

### IV. Forms of Sentences

Where a limitation of a first claim would cover one of a feature as well as more than one of a feature (e.g., a limitation such as “at least one widget” covers one widget as well as more than one widget), and where in a second claim that depends on the first claim, the second claim uses a definite article “the” to refer to the limitation (e.g., “the widget”), this does not imply that the first claim covers only one of the feature, and this does not imply that the second claim covers only one of the feature (e.g., “the widget” can cover both one widget and more than one widget).

When an ordinal number (such as “first”, “second”, “third” and so on) is used as an adjective before a term, that ordinal number is used (unless expressly specified otherwise) merely to indicate a particular feature, such as to distinguish that particular feature from another feature that is described by the same term or by a similar term. For example, a “first widget” may be so named merely to distinguish it from, e.g., a “second widget”. Thus, the mere usage of the ordinal numbers “first” and “second” before the term “widget” does not indicate any other relationship between the two widgets, and likewise does not indicate any other characteristics of either or both widgets. For example, the mere usage of the ordinal numbers “first” and “second” before the term “widget” (1) does not indicate that either widget comes before or after any other in order or location; (2) does not indicate that either widget occurs or acts before or after any other in time; and (3) does not indicate that either widget ranks above or below any other, as in importance or quality. In addition, the mere usage of ordinal numbers does not define a numerical limit to the features identified with the ordinal numbers. For example, the mere usage of the ordinal numbers “first” and “second” before the term “widget” does not indicate that there must be no more than two widgets.

When a single device or article is described herein, more than one device/article (whether or not they cooperate) may alternatively be used in place of the single device/article that is described. Accordingly, the functionality that is described as being possessed by a device may alternatively be possessed by more than one device/article (whether or not they cooperate).

Similarly, where more than one device or article is described herein (whether or not they cooperate), a single device/article may alternatively be used in place of the more than one device or article that is described. For example, a plurality of computer-based devices may be substituted with a single computer-based device. Accordingly, the various functionality that is described as being possessed by more than one device or article may alternatively be possessed by a single device/article.

The functionality and/or the features of a single device that is described may be alternatively embodied by one or more other devices which are described but are not explicitly described as having such functionality/features. Thus, other embodiments need not include the described device itself, but rather can include the one or more other devices which would, in those other embodiments, have such functionality/features.

### V. Disclosed Examples and Terminology are Not Limiting

Neither the Title nor the Abstract in this specification is intended to be taken as limiting in any way as the scope of the disclosed invention(s). The title and headings of sections provided in the specification are for convenience only, and are not to be taken as limiting the disclosure in any way.

Numerous embodiments are described in the present application, and are presented for illustrative purposes only. The described embodiments are not, and are not intended to be, limiting in any sense. The presently disclosed invention(s) are widely applicable to numerous embodiments, as is readily apparent from the disclosure. One of ordinary skill in the art will recognise that the disclosed invention(s) may be practised with various modifications and alterations, such as structural, logical, software, and electrical modifications. Although particular features of the disclosed invention(s) may be described with reference to one or more particular embodiments and/or drawings, it should be understood that such features are not limited to usage in the one or more particular embodiments or drawings with reference to which they are described, unless expressly specified otherwise.

The present disclosure is not a literal description of all embodiments of the invention(s). Also, the present disclosure is not a listing of features of the invention(s) which must be present in all embodiments.

Devices that are described as in communication with each other need not be in continuous communication with each other, unless expressly specified otherwise. On the contrary, such devices need only transmit to each other as necessary or desirable, and may actually refrain from exchanging data most of the time. For example, a machine in communication with another machine via the Internet may not transmit data to the other machine for long period of time (e.g. weeks at a time). In addition, devices that are in communication with each other may communicate directly or indirectly through one or more intermediaries.

A description of an embodiment with several components or features does not imply that all or even any of such components/features are required. On the contrary, a variety of optional components are described to illustrate the wide variety of possible embodiments of the present invention(s). Unless otherwise specified explicitly, no component/feature is essential or required.

Although process steps, operations, algorithms or the like may be described in a particular sequential order, such processes may be configured to work in different orders. In other words, any sequence or order of steps that may be explicitly described does not necessarily indicate a requirement that the steps be performed in that order. The steps of processes described herein may be performed in any order practical. Further, some steps may be performed simultaneously despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary to the invention(s), and does not imply that the illustrated process is preferred.

Although a process may be described as including a plurality of steps, that does not imply that all or any of the steps are preferred, essential or required. Various other embodiments within the scope of the described invention(s) include other processes that omit some or all of the described steps. Unless otherwise specified explicitly, no step is essential or required.

Although a process may be described singly or without reference to other products or methods, in an embodiment the process may interact with other products or methods. For example, such interaction may include linking one business model to another business model. Such interaction may be provided to enhance the flexibility or desirability of the process.

Although a product may be described as including a plurality of components, aspects, qualities, characteristics and/or features, that does not indicate that any or all of the plurality are preferred, essential or required. Various other embodiments within the scope of the described invention(s) include other products that omit some or all of the described plurality.

An enumerated list of items (which may or may not be numbered) does not imply that any or all of the items are mutually exclusive, unless expressly specified otherwise. Likewise, an enumerated list of items (which may or may not be numbered) does not imply that any or all of the items are comprehensive of any category, unless expressly specified otherwise. For example, the enumerated list “a computer, a laptop, a PDA” does not imply that any or all of the three items of that list are mutually exclusive and does not imply that any or all of the three items of that list are comprehensive of any category.

An enumerated list of items (which may or may not be numbered) does not imply that any or all of the items are equivalent to each other or readily substituted for each other.

All embodiments are illustrative, and do not imply that the invention or any embodiments were made or performed, as the case may be.

“Comprises/comprising” and “includes/including” when used in this specification is taken to specify the presence of stated features, integers, steps or components but does not preclude the presence or addition of one or more other features, integers, steps, components or groups thereof. Thus, unless the context clearly requires otherwise, throughout the description and the claims, the words ‘comprise’, ‘comprising’, ‘includes’, ‘including’ and the like are to be construed in an inclusive sense as opposed to an exclusive or exhaustive sense; that is to say, in the sense of “including, but not limited to”.

We claim:

1. A holder for an electronic or the like device configured to move between a closed position and an open position, the device holder including:
a first resiliently deformable member including a first end and a second end;
a second resiliently deformable member including a first end and a second end, the second resiliently deformable member being connected to the first resiliently deformable member at the respective first ends; and
a first engaging formation connected to the second end of the first resiliently deformable member;
a second engaging formation connected to the second end of the second resiliently deformable member,
wherein, in the closed position, the first resiliently deformable member and the second resiliently deformable member are coplanar, and
wherein in the open position, the second end of the first resiliently deformable member and the second end of the second resiliently deformable member are disposed away from each other to hold an electronic device between the engaging formations of the first resiliently deformable member and the second resiliently deformable member, when in use.

2. The device holder of claim 1, wherein in the open position, the first resiliently deformable member and the second resiliently deformable member deflect to accommodate the electronic device between the engaging formations.

3. The device holder of claim 2, wherein the deflection of the first resiliently deformable member and the second resiliently deformable member provides a gripping force to hold the electronic device between the engaging formations.

4. The device holder of claim 1, wherein first resiliently deformable member is integrally formed with the second resiliently deformable member.

5. The device holder of claim 1, wherein the first engaging formation is integrally formed with the first resiliently deformable member and second engaging formation is integrally formed with the second resiliently deformable member.

6. The device holder of claim 1, wherein the first engaging formation includes an end region of the second end of the first resiliently deformable member and a first tab integrally formed with the end region of the first resiliently deformable member.

7. The device holder of claim 6, wherein the second engaging formation includes an end region of the second end of the second resiliently deformable member a second tab integrally formed with the end region of the second resiliently deformable member.

8. The device holder of claim 7, wherein the first tab is configured to deflect relative to the first resiliently deformable member and the second tab is configured to deflect relative to the second resiliently deformable member, such that, in use, at least a portion of one side of the electronic device is engaged between the end region of the second end of the first resiliently deformable member and the first tab and at least a portion of an opposite side of the electronic device is engaged between an end region of the second end of the second resiliently deformable member and the second tab.

9. The device holder of claim 1, wherein the first end of the first resiliently deformable member defines a first foot and the second end of the second resiliently deformable member defines a second foot, such that in use, when the device holder is in the open position, the first foot and the second foot support the device holder and the electronic device when the device holder is placed on a surface.

10. The device holder of claim 1, wherein the first resiliently deformable member and the first tab define an acute angle to engage at least a portion of one side of the electronic device therebetween, when in use.

11. The device holder of claim 1, wherein the second resiliently deformable member and the second tab define an acute angle to engage at least a portion of the opposite side of the electronic device therebetween, when in use.

12. The device holder of claim 1, further including a third member connected to the first resiliently deformable member, the third member including a mounting region configured for hanging the device holder from a formation.

13. The device holder of claim 12, in which the third member is integrally formed with the second end of the first resiliently deformable member.

14. The device holder of claim 12, wherein the mounting region is an aperture.

15. The device holder of claim 12, wherein the third member is resiliently deformable.

16. The device holder of claim 12, wherein the third member includes a backing region which is connected to the first resiliently deformable member to provide a rear outer of the device holder.

17. The device holder of claim 12, wherein the third member extends beyond the second end of the first resiliently deformable member to provide a front outer that is pivotal about the second end of the first resiliently deformable member.

18. The device holder of claim 17, wherein the front outer is pivotal to sandwich the first resiliently deformable member and the second resiliently deformable member between the front outer and the rear outer.

19. The device holder of claim 18, wherein the front outer includes the aperture for mounting the device holder from a formation.

20. The device holder of claim 19, wherein one or more selected from the first resiliently deformable member, the second resiliently deformable member, and the third member is configured for displaying usage instructions and/or advertising graphics.

21. (canceled)

22. (canceled)
